(19) United States
(12) Patent Application Publication
(10) Pub. No.: US 2011/0156092 A1
(43) Pub. Date: Jun. 30, 2011

(54) SMT ENCAPSULATION BODY OF A LIGHT-EMITTING DIODE WITH A WIDE-ANGLE ILLUMINATION LIGHT SHAPE

(75) Inventors: CHIA-HAN HSIEH, TAOYUAN HSIEN (TW); MING-YEN CHEN, TAOYUAN HSIEN (TW)

(73) Assignee: LUMENMAX OPTOELECTRONICS CO., LTD., TAOYUAN HSIEN (TW)

(21) Appl. No.: 12/649,757

(22) Filed: Dec. 30, 2009

(51) Int. Cl. H01L 33/00

(52) U.S. Cl. 257/100; 257/E33.059

(57) ABSTRACT

An SMT encapsulation body of a light-emitting diode with a wide-angle illumination light shape, comprising: a) a substrate; b) an LED die mounted on the substrate by use of SMT; and c) an encapsulation body positioned around the LED die in the shape of a double dome at the top thereof with the center at a lower position such that the illumination light shape of the light-emitting diode becomes to be a wide-angle and elongated body. The encapsulation body may be formed either in the shape of a batwing or in the shape of a double batwing symmetrically positioned in a cross way. In this way, the light-emitting diode achieves a wide-angle illumination light shape fulfilling the requirements of a certain purpose without the use of the double optical effect of the lens. Meanwhile, the drawbacks of the conventional structure are resolved. Moreover, an increased efficiency in using the light source is ensured.

### BACKGROUND OF THE INVENTION

1. Field of the Invention

The invention relates to an encapsulation of a light-emitting diode, and more particularly to an encapsulation body of a light-emitting diode with a wide-angle illumination light shape.

2. Description of the Related Art

Traditional light sources are mostly incandescent lamps or halogen lamps. The shortcomings of these light sources are less efficient. In other words, most of the electric energy is converted into heat that is distributed in the air. Moreover, they have the drawback of short life.

With the environmental trend of saving power and reducing carbon emissions, light-emitted diodes with low power consumption have been gradually employed for replacing the conventional incandescent lamps or halogen lamps.

As shown in FIG. 1, which illustrates a schematic drawing of a conventional LED projecting light, the LED 10 substantially includes a substrate 11, an LED die 12, and a semicircular packaging body 13. However, the projected light of the LED 10 is concentrated only at the central part of the head due to the restricted illumination angle θ such that the illumination light shape is substantially circular or elliptical (similar to circular shape). As a result, the light efficiency is low. Moreover, the standard and the requirements of the street lamps can't be fulfilled.

As shown in FIG. 2, the LED 10 used for street lamps must be fitted with a lens 20 in addition to the substrate 11, the LED die 12, and the semicircular packaging body 13. By means of the double optical effect, the illumination angle θ1 is increased to fulfill the requirements of the illumination light shape of the street lamps.

Although the application of the lens 20 to the LED 10 may fulfill the requirements of the illumination light shape of the street lamps, the lens 20 will increase the entire area of the light body. Moreover, the assembly is not easy. In addition, the production cost will be increased correspondingly. Therefore, a further improvement is required.

### SUMMARY OF THE INVENTION

An object of the invention is to provide an SMT encapsulation body of a light-emitting diode with a wide-angle illumination light shape that achieves a wide-angle illumination light shape fulfilling the requirements of a certain purpose without the use of the double optical effect of the lens. Meanwhile, the drawbacks (such as the difficult assembly and the increased cost) of the conventional structure are resolved. Moreover, an increased efficiency in using the light source is ensured.

In order to achieve the above-mentioned objects, the invention includes:
a) a substrate;
b) an LED die mounted on the substrate by use of SMT (surface mount technique); and
c) an encapsulation body positioned around the LED die in the shape of a double dome ( [symbol] ) at the top thereof with the center at a lower position such that the illumination light shape of the light-emitting diode becomes to be a wide-angle and elongated body.

### BRIEF DESCRIPTION OF THE DRAWINGS

The accomplishment of this and other objects of the invention will become apparent from the following descriptions and its accompanying figures of which:

FIG. 1 is a schematic drawing of a conventional LED structure and the illumination thereof;

FIG. 2 is a schematic drawing of another conventional LED structure and the illumination thereof;

FIG. 3 is a perspective view of a preferred embodiment of an LED structure in accordance with the invention;

FIG. 4 is a side view of the preferred embodiment of the LED structure in accordance with the invention;

FIG. 5 is a schematic drawing of the LED structure of the invention and the illumination thereof;

FIG. 6 is a perspective view of another embodiment of the LED structure in accordance with the invention;

FIG. 7 is a top view of another embodiment of the LED structure in accordance with the invention;

FIG. 8 is a schematic drawing of another embodiment of the LED structure of the invention and the illumination thereof;

FIG. 9 is a side view of a further embodiment of an LED structure in accordance with the invention; and

FIG. 10 is a side view of still another embodiment of an LED structure in accordance with the invention.

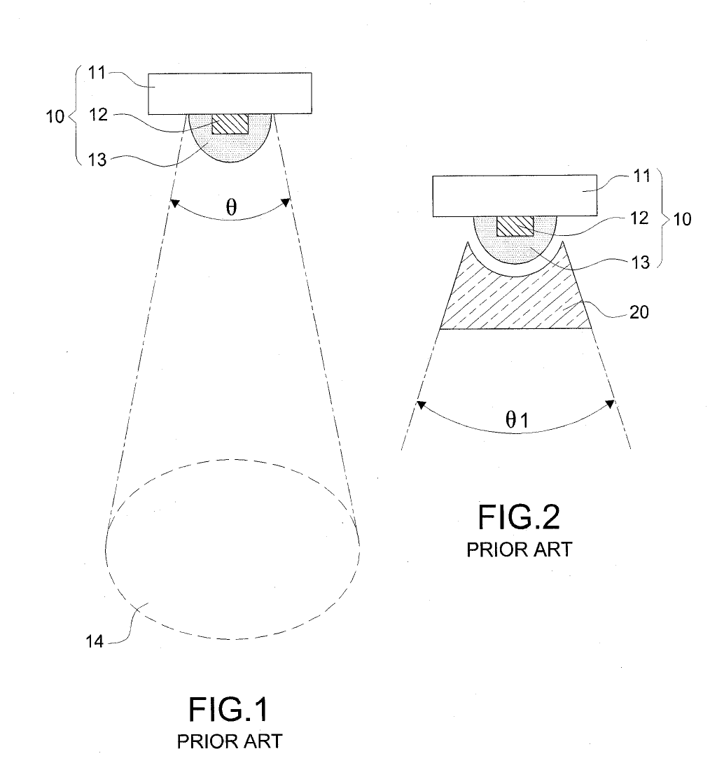

### DETAILED DESCRIPTION OF THE PREFERRED EMBODIMENT

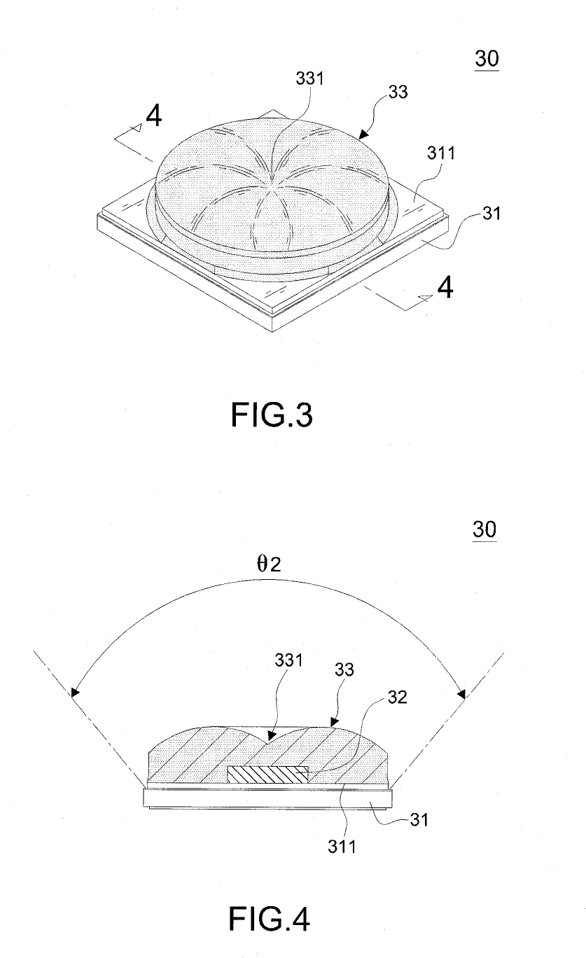

First of all, referring to FIGS. 3 and 4, a preferred embodiment of a light-emitting diode 30 includes a substrate 31, a LED die 32, and an encapsulation body.

The substrate 31 is made of material selected from ceramic, epoxy resin, glass fiber, oxide, or combinations thereof. According to this embodiment, an interface layer 311 is attached to the top surface of the substrate 31. The interface layer 311 may be made of silver paste, but should not restricted thereof.

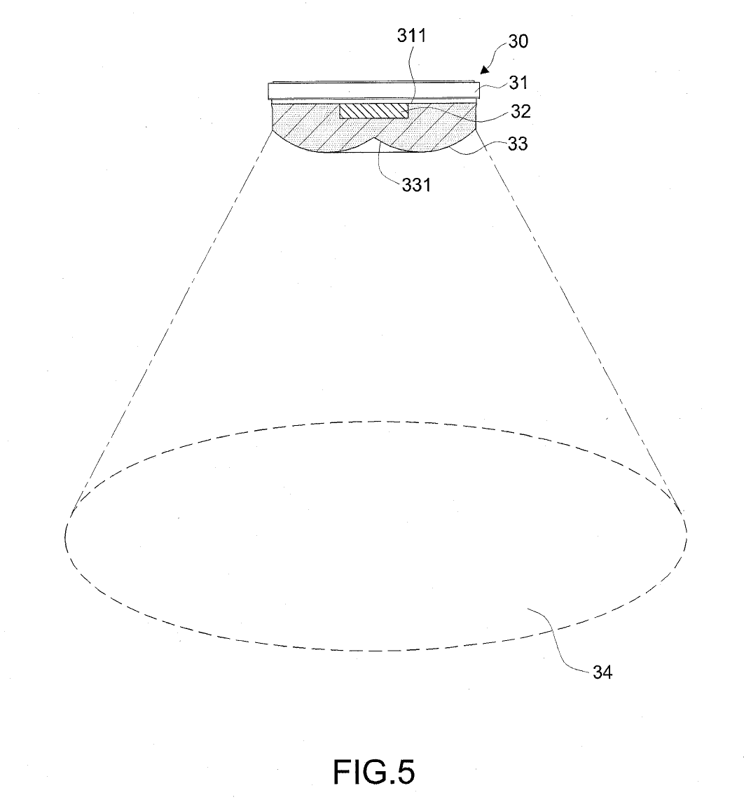

The LED die 32 is mounted on the substrate 31 by use of SMT (surface mount technique). The main feature of the invention lies in that the encapsulation body 33 in shape of a double dome ( [symbol] ) at the top thereof with the center at a lower position is positioned around the LED die 32. In this embodiment, the encapsulation body 33 is made of material selected from silicone gel or epoxy resin. Moreover, the encapsulation body 33 is preferably formed in the molding process, but should not be restricted thereto. Another forming process is also applicable. The encapsulation body 33 is uniquely formed in the shape of a peanut. In other words, the top (331) thereof is formed in the circular shape of a batwing ( [symbol] ) with the center at a lower position. In this way, the projecting light of the LED die 32 has an illumination angle θ2 rising up to ca. 160° after passing through the encapsulation body 33 such that the illumination light shape 34 of the light-emitting diode 30, as shown in FIG. 5, becomes to be a wide-angle and elongated body. In this way, the requirement of the light shape of the street lamps can be fulfilled. Moreover, the structure is easy for assembly and the production cost can be reduced.

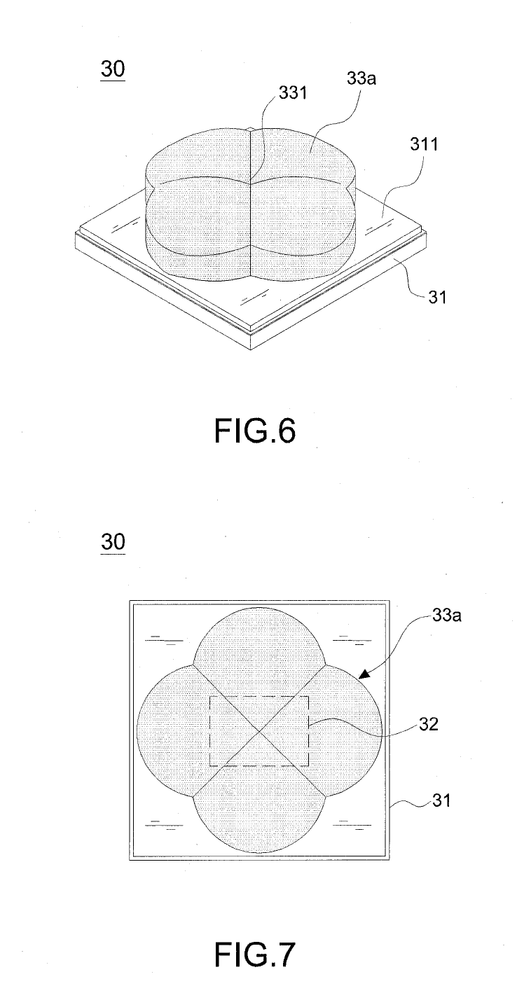

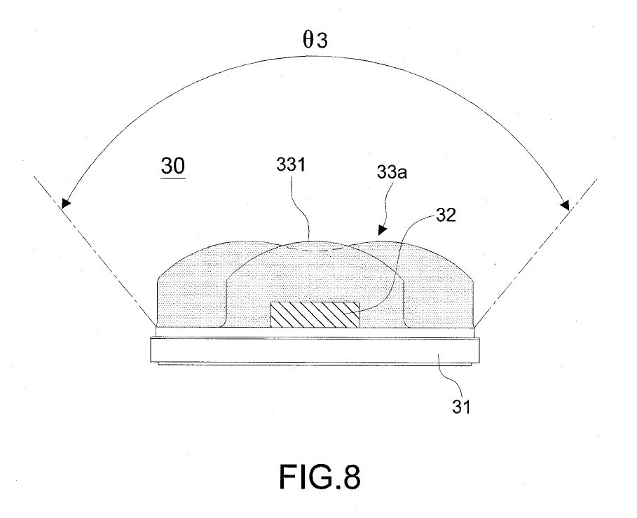

According to another embodiment shown in FIGS. 6 and 7, the structure thereof identical to the above-mentioned embodiment is marked with the same reference signs. The difference lies in that the top (331) of the encapsulation body 33a is formed in the shape of a double batwings ( [symbol] ) symmetrically positioned in a cross way with the center at a lower position. In this way, the projecting light of the LED die 32 has an illumination angle θ3 shown in FIG. 8 after passing through the encapsulation body 33 such that the illumination light shape 34 of the light-emitting diode 30 has a wide angle. Accordingly, a desired illumination light shape is achieved.

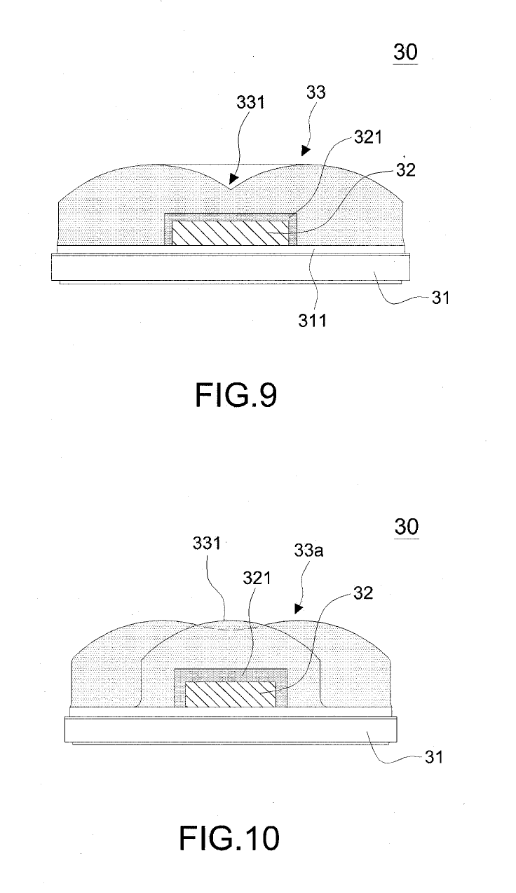

According to a further embodiment shown in FIGS. 9 and 10, the structure thereof identical to the previous embodiment is marked with the same reference signs. The difference lies in that the LED die 32 can emit a blue or ultraviolet light. Moreover, a phosphor encapsulation body 321 is positioned around the LED die 32 such that a white LED is created under the influence of light excitation (but should not restricted thereto). In summary, the invention features the special shape of the encapsulation body 33, 33a and the illumination light shape created thereby.

What is claimed is:

1. An SMT encapsulation body of a light-emitting diode (LED) with a wide-angle illumination light shape, comprising:
a) a substrate;
b) an LED die mounted on the substrate by use of SMT (surface mount technique); and
c) an encapsulation body positioned around the LED die in the shape of a double dome ( [symbol] ) at the top thereof with the center at a lower position such that the illumination light shape of the light-emitting diode becomes to be a wide-angle and elongated body.

2. The SMT encapsulation body of a light-emitting diode with a wide-angle illumination light shape as recited in claim 1 wherein the encapsulation body is formed in the circular shape of a batwing ( [symbol] ) at the top thereof with the center at a lower position.

3. The SMT encapsulation body of a light-emitting diode with a wide-angle illumination light shape as recited in claim 1 wherein the top of the encapsulation body is formed in the shape of a double batwing ( [symbol] ) symmetrically positioned in a cross way with the center at a lower position.

4. The SMT encapsulation body of a light-emitting diode with a wide-angle illumination light shape as recited in claim 1 wherein the substrate is made of material selected from ceramic, epoxy resin, glass fiber, oxide, or combinations thereof.

5. The SMT encapsulation body of a light-emitting diode with a wide-angle illumination light shape as recited in claim 1 wherein the encapsulation body is made of material selected from silicone gel, epoxy resin or combinations thereof.

6. The SMT encapsulation body of a light-emitting diode with a wide-angle illumination light shape as recited in claim 5 wherein the encapsulation body is formed in a molding process.

7. The SMT encapsulation body of a light-emitting diode with a wide-angle illumination light shape as recited in claim 1 wherein an interface layer is attached to the top surface of the substrate.

8. The SMT encapsulation body of a light-emitting diode with a wide-angle illumination light shape as recited in claim 7 wherein the interface layer is made of silver paste.

9. The SMT encapsulation body of a light-emitting diode with a wide-angle illumination light shape as recited in claim 1 wherein the LED die includes a blue or ultraviolet LED die, and wherein a phosphor encapsulation body is positioned around the LED die such that a white LED is created.
